(19) United States
(12) Patent Application Publication
(10) Pub. No.: US 2016/0240699 A1
(43) Pub. Date: Aug. 18, 2016

(54) METHOD FOR STRUCTURING LAYERS OF OXIDIZABLE MATERIALS BY MEANS OF OXIDATION AND SUBSTRATE HAVING A STRUCTURED COATING

(71) Applicant: FRAUNHOFER-GESELLSCHAFT ZUR FÖRDERUNG DER ANGEWANDTEN FORSCHUNG E.V., München (DE)

(72) Inventors: Matthias KAMP, Freiburg (DE); Jonas BARTSCH, Freiburg (DE); Markus GLATTHAAR, Horben (DE)

(73) Assignee: FRAUNHOFER-GESELLSCHAFT ZUR FÖRDERUNG DER ANGEWANDTEN FORSCHUNG E.V., München (DE)

(21) Appl. No.: 15/024,749

(22) PCT Filed: Sep. 18, 2014
(86) PCT No.: PCT/EP2014/069880

§ 371 Date: Mar. 24, 2016

(30) Foreign Application Priority Data
Sep. 26, 2013 (DE) 10 2013 219 342.4

(51) Int. Cl. H01L 31/02; H01L 31/0224; H01L 31/18; C23C 28/00

(52) U.S. Cl. CPC H01L 31/02008; C23C 28/32; H01L 31/022441; H01L 31/18

(57) ABSTRACT

The invention relates to a method for structuring layers of oxidizable materials. At least one layer, disposed on a substrate, of an oxidizable material is hereby subjected to local oxidation with at least one oxidation step. In the case of the latter, at least one selected region of the layer of the oxidizable material is oxidized such that the layer, after oxidation, is subdivided into regions, which are electrically insulated from each other, by at least one oxidized region extending across the entire layer thickness after the oxidation.

The present invention relates to a method for structuring layers of oxidisable materials. At least one layer, disposed on a substrate, of an oxidisable material is hereby subjected to local oxidation with at least one oxidation step. In the case of the latter, at least one selected region of the layer of oxidisable material is oxidised so that the layer, after oxidation, is sub-divided into regions, which are electrically insulated from each other, by at least one oxidised region extending over the entire layer thickness. Furthermore, the present invention also relates to a substrate with structured coating. The substrate thereby has a layer of an oxidisable material which is sub-divided locally into at least two regions, which are electrically insulated from each other, by at least one oxidised region.

Aluminium has numerous advantages in various applications as layer material, in particular as contact material for solar cells, such as for example good electrical contact formation both for p-type and n-type silicon, good reflection properties, a high conductivity value and a low material price. Aluminium can be applied relatively simply over the entire surface on substrates (e.g. solar cells) by means of vapour-deposition processes. Such processes are used for example already in back-contact solar cells (BC solar cells).

Relative to the most frequently produced solar cells with front- and back metallisation, BC solar cells, in which the entire metallisation is found on the cell back, have a significant efficiency advantage. As a result of the lack of front contacts, significantly more light can be used for current generation. The potential of the cell concept and the industrial use have been demonstrated already with solar cell efficiencies of 23.6% and module efficiencies of 21.2% (D. D. Smith, P. J. Cousins, A. Masad, “Generation III High Efficiency Lower Cost Technology: Transition to Full Scale Manufacturing”, Photovoltaic Specialists Conference (PVSC), 38th IEEE, 2012).

In this, but also in other applications, the metallic layers must be structured in order to achieve for example separation of p-type and n-type regions. For BC solar cells, merely one structuring method has to date proved its worth, which is also described in U.S. Pat. No. 7,388,147. For this method, an electroplating protective varnish and an etching process are necessary. Generally, firstly a layer stack made of three PVD layers (e.g. aluminium, titanium-tungsten and copper) is applied. On the PVD copper layer, an electroplating protective varnish is applied in order that further copper can be grown galvanically locally. After applying a protective layer made of tin or silver, the electroplating protective varnish is removed and an additional etching step for removing the PVD layers in the ungalvanised regions is necessary. These metallisation processes are relatively complex and expensive. Because of the expensive production costs, there are only a few businesses which intentionally use the cell concept of the BC solar cell.

In previously known applications, in which aluminium layers are oxidised (anodising processes), the oxidation takes place merely superficially so that only a part of the aluminium layer is oxidised to form aluminium oxide. The fact that the aluminium layer remains under the formed aluminium oxide layer leads to very good adhesion between the layers. The process serves in general for the purpose of increasing the thickness of the natural oxide layer in order to achieve specific physical properties. One property is the electrical insulation effect of the surface, as a result of which oxidised aluminium surfaces are used as dielectric in capacitors and current rectifiers.

In the case of standard anodising processes, the aluminium layer is oxidised merely on the surface thereof in order to make the latter resistant. In order to produce a sufficiently thick and resistant aluminium oxide layer, relatively long process times are therefore necessary. Mainly, the standard anodising process is used for processing aluminium parts in aircraft construction and for finishing household goods and furniture.

U.S. Pat. No. 4,936,957 A describes a use for anodising processes on silicon wafers. Here, an aluminium layer is anodised over the whole surface in order to produce an insulation layer relative to the wafer. The aluminium layer is not thereby completely oxidised through. In addition, a multistep process is used, from which various aluminium oxide layers result (hard-anodised aluminium/soft-anodised aluminium).

A further application in the field of semiconductor technology is described in DE 2540301 A1. Here, an aluminium layer is oxidised superficially (not completely over the entire layer thickness) in order to improve adhesion of a second metal layer applied thereon.

By means of such approaches, the electrical insulation of metallic regions from each other is not however achieved.

Starting from the state of the art, it is the object of the present invention to indicate a rapid and economical method for structuring layers of oxidisable materials.

This object is achieved, with respect to the method, by the features of patent claim 1 and, with respect to a substrate, by the features of patent claim 17. The dependent patent claims thereby represent advantageous developments. According to the invention, a method for structuring layers of oxidisable materials is hence indicated. At least one layer, disposed on a substrate, of an oxidisable material is hereby subjected to local oxidation with at least one oxidation step. In the case of the latter, at least one selected region of the layer of oxidisable material is oxidised so that the layer, after oxidation, is sub-divided into regions, which are electrically insulated from each other, by at least one oxidised region extending over the entire layer thickness.

The invention is characterised in that the structuring of the layers is effected by local oxidation over the entire layer thickness. It is consequently ensured that the layer, after oxidation, is sub-divided into regions, which are electrically insulated from each other, by at least one oxidised region extending over the entire layer thickness.

According to the invention, it was realised that the claimed method, in comparison with methods described in the state of the art, represents a significantly simpler, faster and more economical process for structuring layers of oxidisable materials, such as e.g. aluminium.

Expensive masking processes and complicated, risky laser processes can be dispensed with, which represents a significant advantage relative to the method known in the state of the art. Furthermore, the chemicals required for the method according to the invention are inexpesive mass-produced chemicals, as a result of which again significant cost advantages result. Furthermore, a relatively simple technical implementation under plant engineering aspects is conceivable for the method according to the invention.

A preferred variant of the method provides that the oxidation is electrochemical oxidation, chromatising or phosphatising.

The method according to the invention can be characterised in that the oxidised region, which is produced after the last oxidation step, has an oxidised layer of oxidisable material or consists thereof. Preferably, the oxidised layer has a layer thickness of 0.01-10 μm, particularly preferably of 0.1-2 μm, in particular of 0.3-1 μm.

The layer can be oxidised such that the width of the at least one oxidised region has a width of ≦100 μm, preferably 10 to 100 μm, particularly preferably 30 to 100 μm.

According to the invention, the oxidation of the layer of oxidisable material is effected using an oxidising medium and also a metering device for metering the oxidising medium. During oxidation, the oxidising medium is thereby in contact both with the metering device and with the layer of oxidisable material. In addition, an electrical voltage, in particular of 1-100 V, preferably 10-60 V, particularly preferably 12-30 V, is applied between the metering device and the layer of oxidisable material, by means of which a charge transport through the oxidising medium results. By means of this, the oxidation according to the invention of the layer finally results.

Furthermore it is preferred that the applied electrical voltage and hence the charge transport through the oxidising medium is pulsed.

A further preferred variant provides that there is used, as oxidising medium, a conductive liquid medium, in particular a viscous, conductive, liquid medium, preferably an oxidising acid. For particular preference, sulphuric acid, phosphoric acid, oxalic acid or chromic acid is used.

In a further preferred variant of the method, the metering device used preferably concerns a stamp, in particular a stamp made of a chemically inert, conductive material. As chemically inert, conductive material, preferably titanium, stainless steel, platinum or aluminium is thereby used. For particular preference, the metering device represents a cathode.

Furthermore, it is preferred that the surface of the stamp has webs, in particular made of a chemically inert, conductive material, preferably titanium, stainless steel, platinum or aluminium. In this preferred variant of the method, the stamp is immersed firstly in the oxidising medium, preferably before oxidation, so that the webs are made wet with the oxidising medium. Likewise, the possibility exists of wetting the oxidisable material with the oxidising medium. Subsequently, the stamp can be contacted with the layer of oxidisable material via the oxidising medium wetting the webs.

By means of this variant of the method according to the invention, local oxidation can be achieved in a simple manner. Ultimately, oxidation will only be effected wherever the oxidising medium contacts the layer. Since merely the webs of the stamp are made wet with the oxidising medium, the region of the oxidation is locally limited. If, in contrast, the oxidisable material is made wet with the oxidising medium over the entire surface, local oxidation can likewise take place since the spacing between the webs of the stamp and the surface of the oxidisable material is very small and consequently the local charge transport through the oxidising medium at these places is preferred. The oxidation is effected finally over the entire layer thickness. The webs are kept narrow with a width of approx. 30-100 μm, according to the planned structure. With respect to the geometry of the webs and the surface property thereof, various configurations are conceivable. Thus, for improving the stability of the webs, a geometry which tapers conically towards the tip can be used. For better wetting of the surface, a microscale roughening can be effected.

According to initial tests, flowing of the medium is prevented by a stable meniscus. It is advantageous to achieve as narrow a meniscus as possible in order to enable low structural widths. A further possibility for control resides in applying a very short, very high voltage pulse, which leads to complete oxidation of the layer even before the electrolyte can flow. This approach is of particular interest for morphologically demanding surfaces (e.g. with texturing). Control of the pulse can be effected, in this case, via measurement of the conductivity between stamp and metal layer to be oxidised since both are connected to each other conductively. The current circuit is closed by the oxidising medium. As soon as the electrical conductivity is measured, the surface is made wet and the voltage pulse begins. Likewise, processes with several anodic pulses are conceivable, which influence the ion transport in the oxidising medium so that very narrow opened regions can be produced. A pulse sequence with anodic and cathodic pulses can possibly be used for the purpose of removing the locally oxidised regions in a specific manner during the process, as is practised comparably over the surface with electropolishing processes (or in the case of electrochemical removal). The advantage of such a process is the fact that, before each anodic pulse, the previously formed aluminium oxide was detached and the oxidation of the aluminium can be implemented more easily or with a lower voltage.

For homogeneous wetting of the webs, a specific change in the oxidising medium with respect to the viscosity thereof is advantageous. The viscosity of the medium can be increased for example by crosslinking or water-extracting materials.

In addition, it is possible to process the webs directly in order to improve the wetting capacity with the oxidising medium. If no webs are used, the structuring of the stamp could be produced for example by hydrophobic and hydrophilic regions being produced. Hence, the medium would form a meniscus merely between hydrophilic regions of the stamp and the surface of the material to be oxidised so that the oxidation would likewise take place locally.

In a further preferred variant of the method according to the invention, the surface of the stamp has webs, in particular made of a chemically stable, non-conductive open-cell sponge or felt. The sponge thereby preferably consists of sponge rubber, latex foam or PUR foam. In this variant of the method, the stamp is immersed firstly in the oxidising medium, preferably before oxidation, so that the webs suction up the oxidising medium. Subsequently, the stamp can be contacted with the layer of oxidisable material. Also in this preferred variant of the method, it is possible in a simple manner to achieve local oxidation. In this case, a mechanical contact between the webs and the surface of the material to be oxidised is produced during the oxidation process. Possible flowing of the oxidising medium is prevented by the suction-capacity of the sponge or felt, as a result of which very narrow regions can likewise be oxidised.

In a further preferred embodiment variant of the method according to the invention, the surface of the stamp has webs as seals which are resistant to the oxidising medium. These webs preferably consist of ethylene-propylene-diene rubber. In this variant of the method, the oxidising medium is applied firstly on the layer of oxidisable material before oxidation. Subsequently, the stamp is contacted with the layer of oxidisable material so that the seals which are resistant to the oxidising medium displace the oxidising medium from regions of the layer of oxidisable material which are not to be oxidised.

Furthermore, an embodiment variant of the method according to the invention is preferred, in which the surface of the stamp has webs as seals which are resistant to the oxidising medium. These webs preferably consist of ethylene-propylene-diene rubber. In this variant of the method, the stamp is contacted firstly with the layer of oxidisable material before oxidation. Subsequently, the oxidising medium is applied on regions of the layer of oxidisable material to be oxidised through channels disposed inside the stamp.

In both just-mentioned variants of the method, the location of the oxidation is achieved by the regions of the oxidisable material not to be oxidised being protected against wetting by the oxidising medium, and also electrically. The width of the oxidising regions in this case can be adjusted, on the one hand, via the width of the webs, on the other hand, via the contact pressure of the stamp and the elasticity of the sealing material. Depending on the width of the webs, also introduction of the oxidising medium through the webs is possible, as a result of which the wetting can be better controlled. The sealing material is distinguished preferably by being electrically very well insulating, in addition to the chemical resistance. The oxidation process can then be prevented by two simultaneously acting mechanisms, displacement of the oxidising medium and protection of the surface against the required electrical current, or by a situation of the electrical field which is unfavourable for the regions covered by the stamp with respect to oxidation.

In a further preferred variant of the method according to the invention, the metering device concerns a conductive nozzle, through the nozzle head of which the oxidising medium can emerge continuously. In this variant of the method, the conductive nozzle is guided over the surface of the layer of oxidisable material during oxidation. The needle is thereby connected electrically to the surface of the oxidisable material so that local oxidation of the oxidisable material is possible. The nozzle preferably has a gap or consists thereof, in particular a gap with a length of . . . μm and/or width of . . . μm.

A further preferred variant of the method according to the invention provides that, after the last oxidation step, the at least two regions of the layer, which are electrically insulated from each other, are coated galvanically or chemically with at least one further metal or, after the last oxidation step, the at least one oxidised region of the layer is detached at least partially.

In a further preferred variant of a method according to the invention, after the last oxidation step, the at least two regions of the layer, which are electrically insulated from each other, are coated galvanically or chemically with at least one further metal, and subsequently the at least one oxidised region of the layer is detached at least partially.

A further preferred variant of the method according to the invention provides that, between two of the oxidation steps, the non-oxidised regions of the layer are coated galvanically or chemically with at least one further metal. It is hereby preferred that, after the last oxidation step, the at least one oxidised region of the layer is detached at least partially.

If the oxidisable material concerns aluminium or an aluminium alloy such as e.g. AlSi, and if the at least two regions of the layer, which are insulated from each other, are coated galvanically or chemically with tin or zinc, then this coating is effected preferably using a stannate solution or a zincate solution. During the zincate process, an exchange reaction of aluminium and zinc takes place, as a result of which a zinc layer is formed on the aluminium surface and serves as seed layer for further galvanic deposition of other metals.

The method can be characterised in that it is selected from the group consisting of instantaneous printing methods and relief printing methods, gravure methods, flatbed methods and porous printing methods, preferably is selected from the group consisting of inkjet methods, dispensing methods and screen printing methods.

The method can be a screen printing method, preferably the metering device comprising a doctor blade or consisting thereof and an electrically conductive screen being particularly preferably used. In particular, an electrical voltage of 1-100 V, preferably 10-60 V, particularly preferably 12-30 V, is applied between the screen and the layer, by means of which the result is a current flow through the oxidising medium.

The present invention likewise comprises a substrate with structured coating, the substrate having a layer of an oxidisable material which is sub-divided locally into at least two regions, which are electrically insulated from each other, by at least one oxidised region.

The oxidisable material thereby preferably concerns a metal, a semi-metal or an alloy, in particular selected from the group consisting of aluminium, tantalum, niobium, titanium, tungsten, zirconium or silicon and also alloys hereof, preferably aluminium alloys, particularly preferably AlSi.

In a preferred embodiment of the substrate according to the invention, the substrate concerns a solar cell, preferably a back-contact solar cell.

Furthermore, it is preferred that the layer of oxidisable material has a layer thickness of 0.01-10 μm, preferably of 0.1-2 μm, particularly preferably of 0.3-1 μm.

A further preferred embodiment provides that the width of the at least one oxidised region decreases towards the substrate. The decrease in width is thereby dependent upon the layer thickness and also upon the set process parameters and is up to 20%.

In a further preferred embodiment of the substrate according to the invention, the layer of oxidisable material is sub-divided into two regions, which are electrically insulated from each other, by a meandering oxidised region.

Furthermore, it is preferred that the at least two regions of the layer, which are electrically insulated from each other, are coated galvanically or chemically with at least one further metal, in particular selected from the group consisting of tin, zinc, nickel, copper and silver.

In a further preferred embodiment of the substrate according to the invention, this is produced according to the method according to the invention or according to one of the described variants of the method according to the invention.

The substrate according to the invention can be characterised in that the oxidised region has an oxidised layer of oxidisable material or consists thereof. Preferably the oxidised layer has a layer thickness of 0.01-10 μm, particularly preferably of 0.1-2 μm, further preferably of 0.3-1 μm. In particular, the substrate is a monolithic substrate.

The width of the at least one oxidised region can have a width of ≦100 μm, preferably 10 to 100 μm, particularly preferably 30 to 100 μm.

The present invention is explained in more detail with reference to the subsequent Figures and also examples without restricting the invention to the specific embodiments shown here.

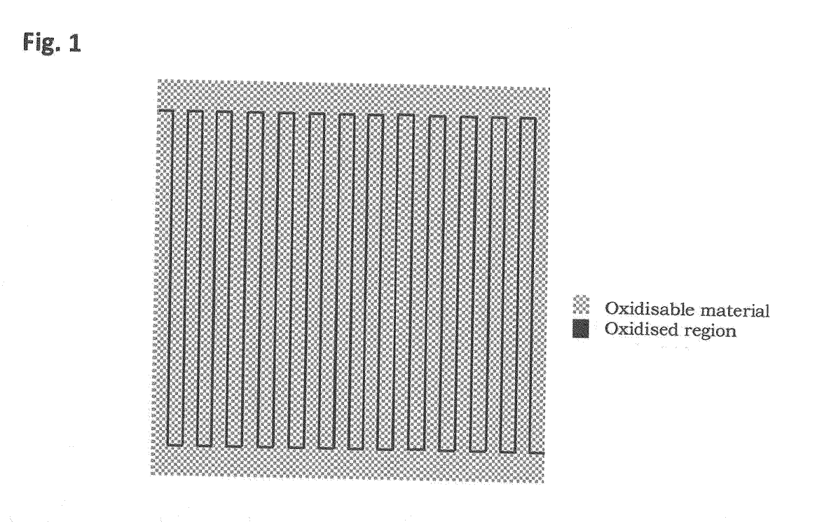

FIG. 1 shows a schematic illustration of a meandering aluminium oxide layer which divides the aluminium layer electrically into two regions.

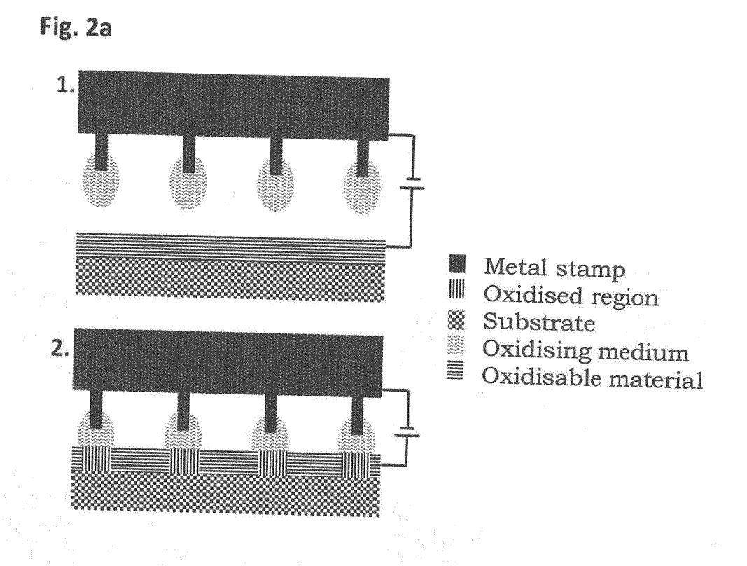

FIG. 2a shows the variant of the method according to the invention in which a stamp with webs made of a chemically inert, conductive material is used. A cross-section of the stamp and of the substrate is thereby shown before and during the oxidation process. In FIG. 2b, the variant of the method according to the invention is shown, in which a stamp with webs made of a chemically stable, non-conductive sponge or felt is used. A cross-section of the stamp and of the substrate is thereby shown before and during the oxidation process.

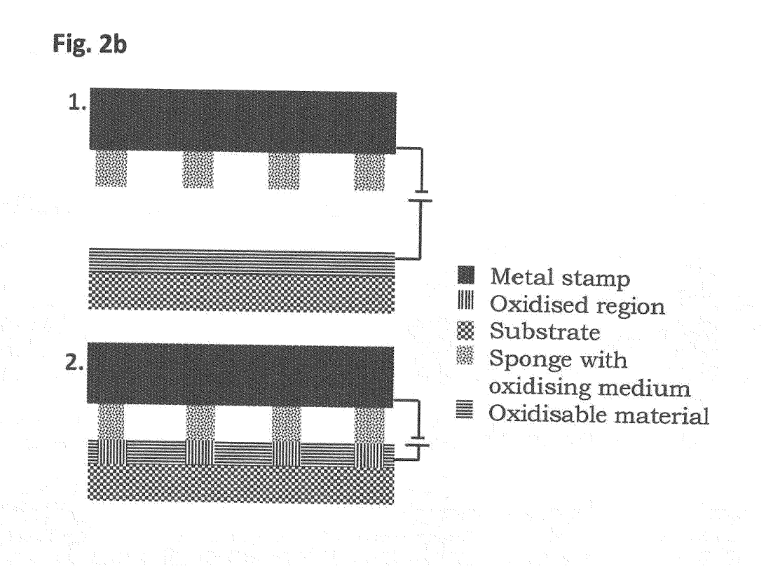

FIG. 3a shows the variant of the method according to the invention during which a stamp with webs as seals which are resistant to the oxidising medium is used and the oxidising medium is firstly applied on the layer of oxidisable material before oxidation. A cross-section of the stamp and of the substrate is thereby shown before and during the oxidation process. In FIG. 3b, the variant of the method according to the invention is shown, in which a stamp with webs as seals which are resistant to the oxidising medium is used and the oxidising medium is applied on regions of the layer of oxidisable material to be oxidised through channels disposed inside the stamp. A cross-section of the stamp and of the substrate is thereby shown before and during the oxidation process. In FIG. 3c, the variant of the method according to the method is shown, in which a conductive nozzle is used, through the nozzle head of which the oxidising medium can emerge continuously. A cross-section of the nozzle and of the substrate is thereby shown during the oxidation process.

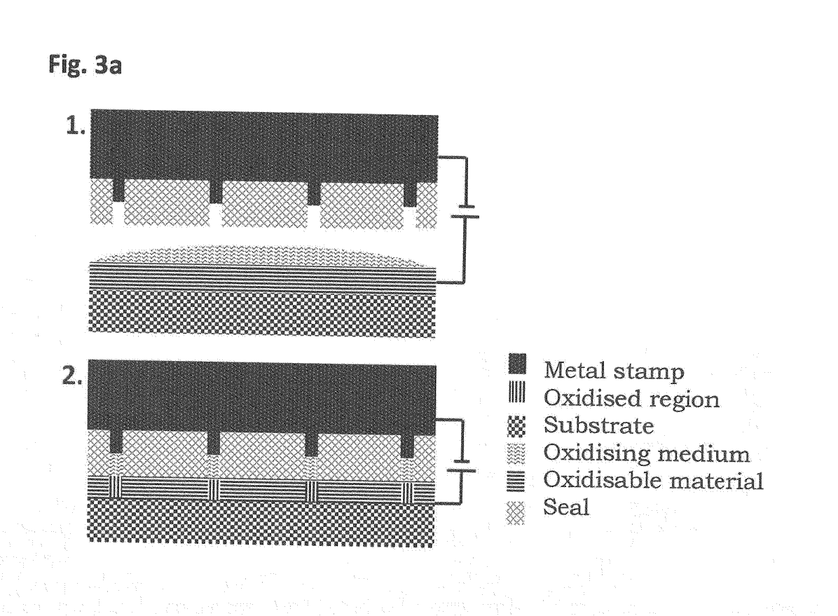

FIG. 4 shows a scanning electron micrograph of the microtome section of an aluminium layer on a silicon wafer, which layer is completely oxidised through by means of electrochemical oxidation. Here, the typical pore structure of the anodically produced aluminium oxide layer is readily visible.

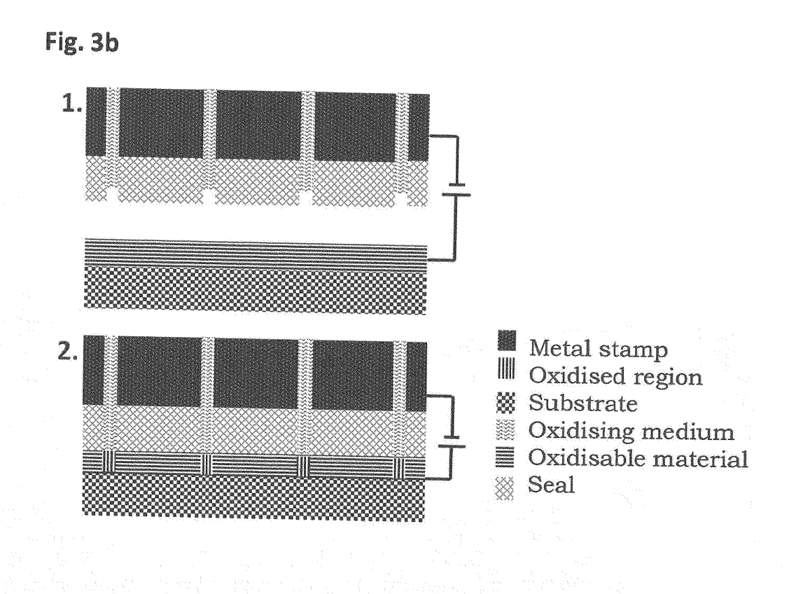

FIG. 5 shows the substrate after complete oxidation. The oxidised region (viewed on the microtome section) is substantially wider at the surface than at the interface to the substrate. The width of the oxidised region therefore decreases towards the substrate. The decrease in width is up to 20%.

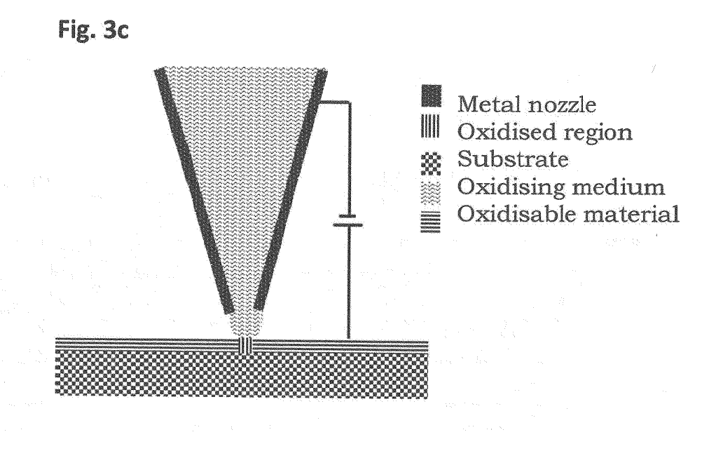

FIG. 6 likewise shows the substrate after complete oxidation, the oxidised region however having been detached thereafter. It can be seen clearly here that the oxidised aluminium which is situated still on the aluminium layer remains adhering.

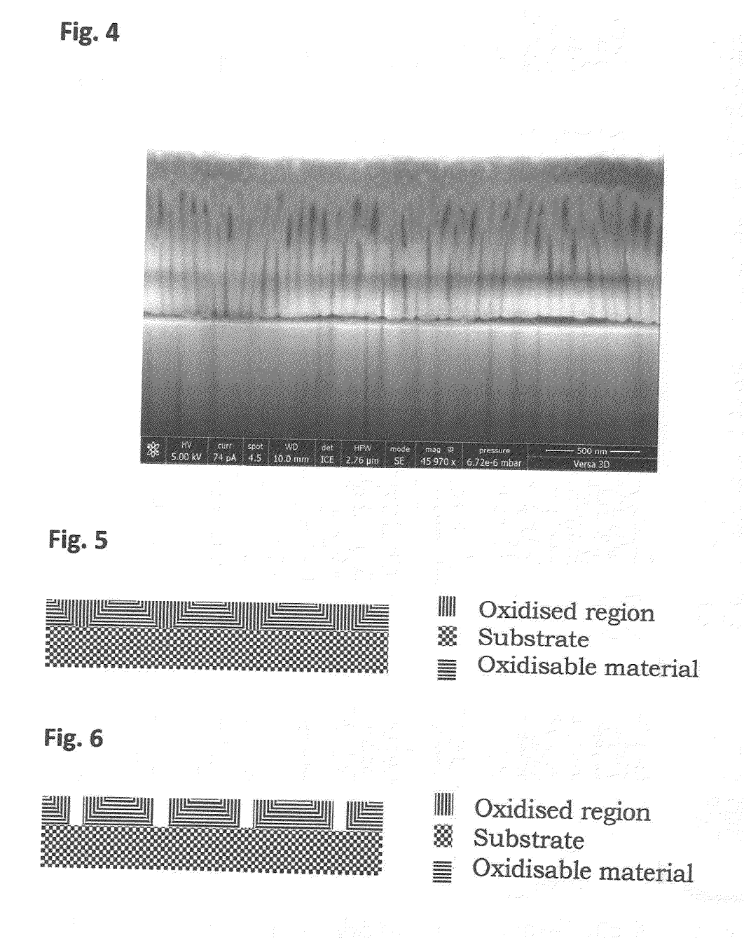

FIG. 7 shows a variant of the method according to the invention in which the method is a screen printing method. The electrochemical processing with electrical contacting of an electrically conductive screen is illustrated. In this embodiment, the metering device (doctor blade) can in addition be contacted electrically.

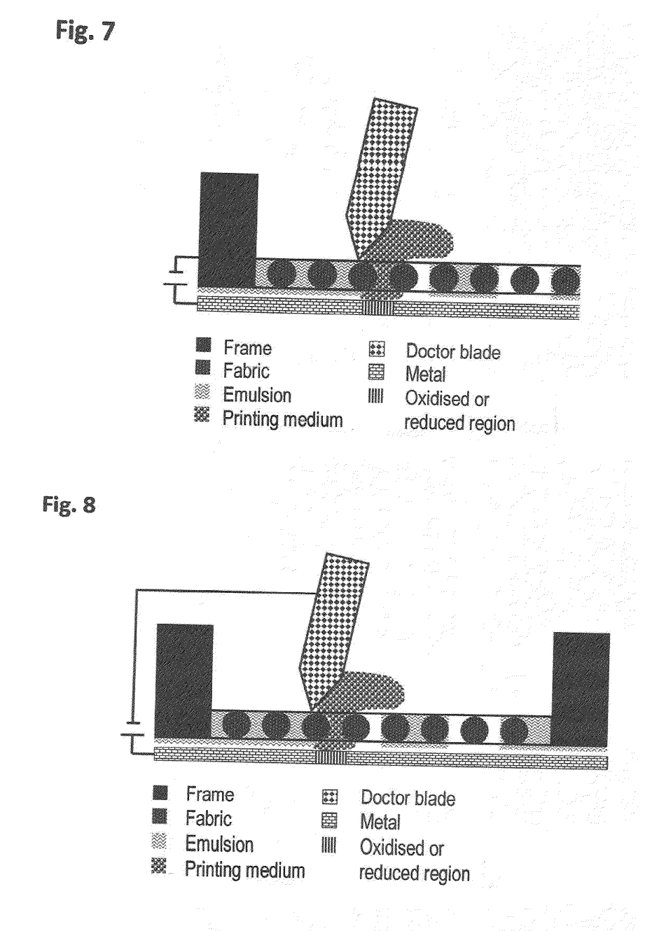

FIG. 8 shows a variant of the method according to the invention, in which the method is a screen printing method. The electrochemical processing with electrical contacting of the metering device (doctor blade) is illustrated. In this embodiment, also the screen can be contacted electrically in the case of using an electrically conductive screen.

### EMBODIMENTS

A preferred application of the invention is the structuring of metal layers which are used for contacting solar cells. Aluminium is here the material of most interest because of its advantageous optical and electrical properties, besides titanium. Likewise, electrolytically produced aluminium oxide layers have properties such as transparency and insulation capacity which can be of interest for solar cell processes. Because of the structure thereof, in addition simple possibilities exist for specifically changing these properties.

In one application example, a 0.5 μm thick aluminium layer was deposited by means of PVD on a solar cell with n++pp+ doping structure of the silicon wafer on both sides over the entire surface. On the light-collecting n++ side of the solar cell, sulphuric acid was subsequently applied as oxidising medium. A structured stamp consisting of EPDM material was subsequently pressed at a defined pressure into the regions provided for contact fingers and collector buses. By applying a voltage of 20 V, the regions not provided for metallisation could be oxidised completely within a few seconds. The then optically transparent aluminium oxide could be removed subsequently by applying a flow of compressed air against the edge. In a subsequent zincate process, both n++ and p+ side of the solar cell could be prepared for the subsequent galvanisation with nickel, copper and silver.

In a further application example, a 1 μm thick aluminium layer was deposited over the entire surface on the structured diffused n+ and p+ regions of a back-contact solar cell by means of PVD. The task exists here in the electrical separation of the p- and n- doped regions.

In a first test relating to this application example, the p+ and n+ regions (cf. Ill. 1), disposed in a meandering shape, were separated from each other electrically by means of a stainless steel stamp (cf. Ill. 2a) with sulphuric acid within a few seconds (the measured electrical resistance between the aluminium regions was 60 kOhm). Both regions were subsequently prepared with a zincate process for the subsequent galvanic thickening with nickel, copper and tin.

In a second test relating to this application example, the p+ and n+ regions were disposed in the form of interrupted lines over the solar cell. These lines are intended to be connected via a wire electrode, are very thin and correspondingly can be contacted with difficulty under plant engineering aspects. In a first step, comparable to application example 1, a stamp with EPDM material structures which correspond to the appearance of fingers, was pressed onto the aluminium layer after wetting with sulphuric acid. By applying a voltage, the 1 μm thick aluminium layer was firstly oxidised only on the upper approx. 300 nm. A subsequent zincate process was then effected, despite complete immersion of the wafer, selectively only on the regions protected by the stamp. A galvanic deposition of nickel, copper and silver was possible over the full surface on all finger structures since a current supply and -distribution was assisted by the still unreacted aluminium layer. Subsequently, the remaining layer could be completely oxidised without using masking. The silver layer of the contacts thereby protected the finger regions from oxidation. Separation of the n+ and p+ regions was effected in this second oxidation step.

1-26. (canceled)

27. A method for structuring layers of oxidisable materials, in which at least one layer, disposed on a substrate, of an oxidisable material is subjected to local oxidation with at least one oxidation step, in which at least one selected region of the layer of oxidisable material is oxidised so that the layer, after the last oxidation step, is subdivided into regions, which are electrically insulated from each other, by at least one oxidising region extending over the entire layer thickness, wherein oxidation of the layer is effected utilizing an oxidising medium and also a metering device for metering the oxidising medium, the oxidising medium being in contact, during oxidation, both with the metering device and with the layer, and an electrical voltage of 1-100 V being applied between the metering device and the layer, by means of which a current flow through the oxidising medium results.

28. The method according to claim 27, wherein the oxidised region, which is produced after the last oxidation step, has an oxidised layer of oxidisable material or consists thereof.

29. The method according to claim 27, wherein the layer is oxidised such that the width of the at least one oxidised region has a width of ≦100 μm.

30. The method according to claim 27, wherein the applied electrical voltage and hence the current which flows through the oxidising medium is pulsed.

31. The method according to claim 27, wherein the oxidising medium is a conductive liquid medium.

32. The method according to claim 27, wherein a stamp is utilized as metering device.

33. The method according to claim 27, wherein a stamp is utilized as metering device and wherein the surface of the stamp has webs
a) made of a chemically inert, conductive material, the stamp being immersed firstly in the oxidising medium, so that the webs are made wet with the oxidising medium and subsequently the stamp is contacted with the layer via the oxidising medium wetting the webs; or
b) made of a chemically stable, non-conductive, open-cell sponge, the stamp being immersed firstly in the oxidising medium, so that the webs suction up the oxiding medium, and subsequently the stamp is contacted with the layer; or
c) as seals which are resistant to the oxidising medium, the oxidising medium being applied firstly on the layer before oxidation and the stamp being contacted subsequently with the layer so that the seals which are resistant to the oxidising medium displace the oxidising medium from regions of the layer which are not to be oxidized; or
d) as seals which are resistant to the oxidising medium, the stamp being contacted firstly with the layer before oxidation and the oxidising medium being applied subsequently on regions of the layer to be oxidised through channels disposed inside the stamp.

34. The method according to claim 27, wherein the metering device is a conductive nozzle, through the nozzle head of which the oxidising medium can emerge continuously, the conductive nozzle being guided over the surface of the layer during oxidation.

35. The method according to claim 27, wherein, after the last oxidation step, the at least two regions of the layer, which are electrically insulated from each other, are coated galvanically or chemically with at least one further metal and/or the at least one oxidised region of the layer is detached at least partially.

36. The method according to claim 27, wherein, between two of the oxidation steps, the non-oxidised regions of the layer are coated galvanically or chemically with at least one further metal and the at least one oxidised region of the layer is detached at least partially.

37. The method according to claim 27, wherein the method is selected from the group consisting of instantaneous printing methods, relief printing methods, gravure methods, flatbed methods, porous printing methods and screen printing methods.

38. A substrate with structured coating, the substrate having a layer of an oxidisable material which is subdivided locally into at least two regions, which are electrically insulated from each other, by at least one oxidised region.

39. The substrate according to claim 38, wherein the oxidisable material is a metal, a semi-metal or an alloy.

40. The substrate according to claim 38, wherein the substrate is a solar cell.

41. The substrate according to claim 38, wherein the layer
a) has a layer thickness of 0.01-10 μm; and/or
b) is sub-divided into two regions, which are electrically insulated from each other, by a meandering oxidised region.

42. The substrate according to claim 38, wherein the width of the at least one oxidised region decreases towards the substrate.

43. The substrate according to claim 38, wherein the at least two regions of the layer, which are electrically insulated from each other, are coated galvanically or chemically with at least one further metal.

44. The substrate according to claim 38, wherein the substrate is produced according to the method in which at least one layer, disposed on a substrate, of an oxidisable material is subjected to local oxidation with at least one oxidation step, in which at least one selected region of the layer of oxidisable material is oxidised so that the layer, after the last oxidation step, is subdivided into regions, which are electrically insulated from each other, by at least one oxidising region extending over the entire layer thickness, wherein oxidation of the layer is effected utilizing an oxidising medium and also a metering device for metering the oxidising medium, the oxidising medium being in contact, during oxidation, both with the metering device and with the layer, and an electrical voltage of 1-100 V being applied between the metering device and the layer, by means of which a current flow through the oxidising medium results.

45. The substrate according to claim 38, wherein the oxidised region has an oxidised layer of oxidisable material or consists thereof.

46. The substrate according to claim 38, wherein the width of the at least one oxidised region has a width of ≦100 μm.
